(19) United States
(12) Patent Application Publication
(10) Pub. No.: US 2026/0293191 A1
(43) Pub. Date: Sep. 24, 2026

(54) SEMICONDUCTOR DEVICE, SEMICONDUCTOR MEMORY DEVICE, AND METHOD FOR MANUFACTURING SEMICONDUCTOR DEVICE

(71) Applicant: Kioxia Corporation, Tokyo (JP)

(72) Inventor: Yusuke KASAHARA, Yokkaichi Mie (JP)

(21) Appl. No.: 19/323,802

(22) Filed: Sep. 9, 2025

(30) Foreign Application Priority Data
Mar. 24, 2025 (JP) 2025-048451

(51) Int. Cl. H10D 30/63; H10B 12/00; H10D 1/68; H10D 30/01; H10D 62/10; H10D 62/17; H10D 64/27; H10D 64/68

(52) U.S. Cl. CPC H10D 30/63; H10B 12/33; H10D 30/025; H10D 62/102; H10D 62/115; H10D 62/292; H10D 64/514; H10D 64/519; H10D 64/693; H10D 1/716

(57) ABSTRACT

A semiconductor device includes an oxide semiconductor layer between first and second electrodes in a first direction. The oxide semiconductor layer includes a first region facing a gate electrode, between a second region and a third region. A gate insulating layer is provided between the first region and the gate electrode. In a first cross section parallel to the first direction, a first length, which is a maximum length of the first region in a second direction, is greater than a second length, which is a minimum length of the second region in the second direction, and greater than a third length, which is a minimum length of the third region in the second direction. ½ of a difference between the first length and an average of the second and third lengths, is equal to or greater than 0.75 times a thickness of the gate insulating layer.

### CROSS-REFERENCE TO RELATED APPLICATION

This application is based upon and claims the benefit of priority from Japanese Patent Application No. 2025-048451, filed Mar. 24, 2025, the entire contents of which are incorporated herein by reference.

### FIELD

Embodiments described herein relate generally to a semiconductor device, a semiconductor memory device, and a method for manufacturing a semiconductor device.

### BACKGROUND

An oxide semiconductor transistor that forms a channel in an oxide semiconductor layer has excellent characteristics in that a channel leakage current is extremely small when operating power is turned off. Therefore, for example, the oxide semiconductor transistor is applicable to a switching transistor of a memory cell of a dynamic random access memory (DRAM).

### BRIEF DESCRIPTION OF THE DRAWINGS

FIG. 1 schematically illustrates a cross-sectional view of a semiconductor device according to a first embodiment.

FIG. 2 schematically illustrates another cross-sectional view of the semiconductor device according to the first embodiment.

FIGS. 3-13 schematically illustrate a cross-sectional views of elements to show example process steps of a method for manufacturing the semiconductor device according to the first embodiment.

FIG. 14 schematically illustrates a cross-sectional view of a semiconductor device according to a comparative example.

FIGS. 15-18 schematically illustrate cross-sectional views of elements to show example process steps of a method for manufacturing the semiconductor device according to the comparative example.

FIG. 19 schematically illustrates a cross-sectional view of a semiconductor device according to a first modification example of the first embodiment.

FIG. 20 is an equivalent circuit diagram of a semiconductor memory device according to a second embodiment.

FIG. 21 schematically illustrates a cross-sectional view of the semiconductor memory device according to the second embodiment.

### DETAILED DESCRIPTION

Embodiments provide a semiconductor device having excellent transistor characteristics.

In general, according to an embodiment, a semiconductor device includes a first electrode, a second electrode, an oxide semiconductor layer provided between the first electrode and the second electrode in a first direction, and including a first region, a second region provided between the first region and the first electrode in the first direction, and a third region provided between the first region and the second electrode in the first direction, a gate electrode facing the first region, and a gate insulating layer provided between the first region and the gate electrode, separated from the first electrode, and in contact with the second electrode. In a first cross section parallel to the first direction, a first length, which is a maximum length of the first region in a second direction perpendicular to the first direction, is greater than a second length, which is a minimum length of the second region in the second direction, and greater than a third length, which is a minimum length of the third region in the second direction. A second thickness, which is ½ of a difference between the first length and an average value of the second length and the third length is equal to or greater than 0.75 times a first thickness, which is a thickness of the gate insulating layer in the second direction.

Hereinafter, embodiments of the present disclosure will be described with reference to the drawings. In the following description, the same reference numerals will be assigned to the same or similar members, and description thereof may be omitted as appropriate.

In the present specification, terms of “up”, “down”, “an upper portion”, or “a lower portion” may be used for convenience. The terms of “up”, “down”, “the upper portion”, and “the lower portion” indicate a relative positional relationship in the drawings, and do not define a positional relationship in terms of gravity.

For example, qualitative analysis and quantitative analysis of chemical compositions of members forming a semiconductor device and a semiconductor memory device in the present specification can be performed by secondary ion mass spectrometry (SIMS), energy dispersive X-ray spectroscopy (EDX), and Rutherford back-scattering spectroscopy (RBS). In addition, for example, a transmission electron microscope (TEM) can be used for measuring thicknesses of the members forming the semiconductor device and the semiconductor memory device, a distance between the members, crystal grain sizes, and the like. In addition, for example, an X-ray photoelectron spectroscopy (XPS), a hard X-ray photoelectron spectroscopy (HAXPES), and an electron energy loss spectroscopy (EELS) can be used for identifying forming materials of the members forming the semiconductor device and the semiconductor memory device and for measuring existence ratios of the forming materials.

A term of “metal” in the present specification is a general term for a material having metallic properties, and, for example, a metal compound such as metal nitride or metal carbide having the metallic properties is also included in a range of the “metal”.

### First Embodiment

According to a first embodiment, a semiconductor device includes a first electrode, a second electrode, an oxide semiconductor layer provided between the first electrode and the second electrode in a first direction and including a first region, a second region provided between the first region and the first electrode in the first direction, and a third region provided between the first region and the second electrode in the first direction, a gate electrode facing the first region, and a gate insulating layer provided between the first region and the gate electrode, separated from the first electrode, and in contact with the second electrode. In a first cross section parallel to the first direction, a first length, which is a maximum length of the first region in a second direction perpendicular to the first direction, is greater than a second length, which is a minimum length of the second region in the second direction, and a third length, which is a minimum length of the third region in the second direction, and a second thickness, which is ½ of a difference between the first length and an average value of the second length and the third length, is equal to or greater than 0.75 times a first thickness, which is a thickness of the gate insulating layer in the second direction.

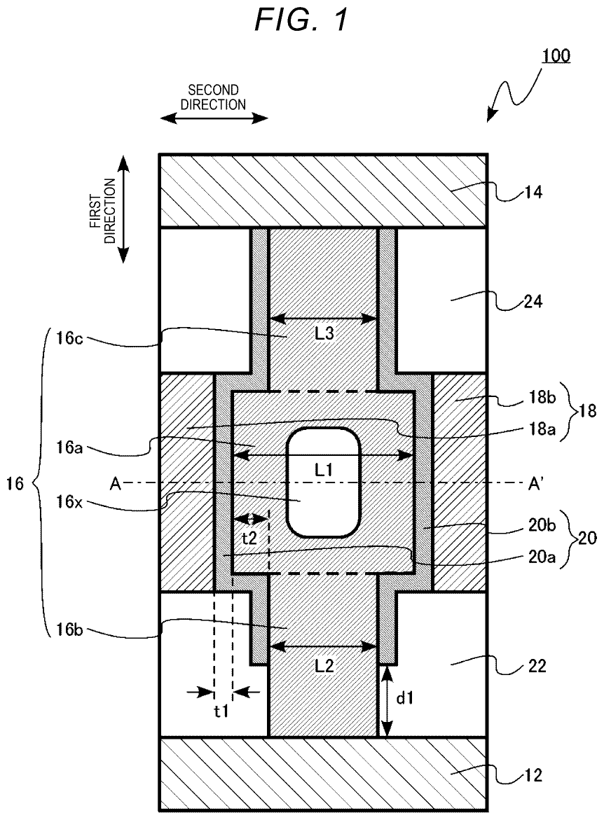

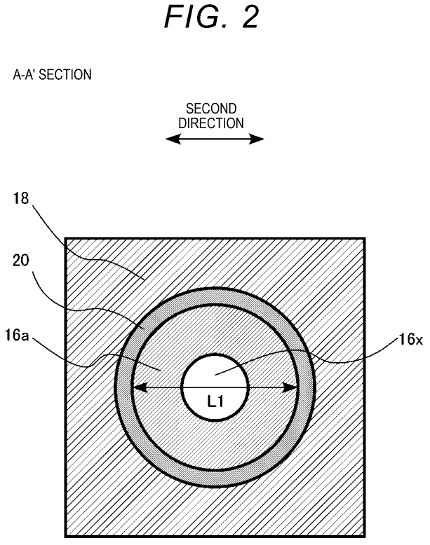

FIGS. 1 and 2 schematically illustrate cross-sectional views of the semiconductor device according to the first embodiment. FIG. 2 illustrates a cross-sectional view taken along line A-A′ in FIG. 1.

In FIG. 1, an up-down direction will be referred to as a first direction. In FIG. 1, a left-right direction will be referred to as a second direction. The second direction is perpendicular to the first direction. The first direction is a direction connecting a lower electrode 12 and an upper electrode 14.

FIG. 1 shows a cross section parallel to the first direction. FIG. 1 shows an example of a first cross section.

The semiconductor device according to the first embodiment is a transistor 100. The transistor 100 is an oxide semiconductor transistor in which a channel is formed in an oxide semiconductor. The transistor 100 includes a gate electrode surrounding an oxide semiconductor layer in which the channel is formed. The transistor 100 is a so-called gate all around (GAA) transistor. The transistor 100 is a so-called vertical transistor.

The transistor 100 includes the lower electrode 12, the upper electrode 14, an oxide semiconductor layer 16, a gate electrode 18, a gate insulating layer 20, a first interlayer insulating layer 22, and a second interlayer insulating layer 24. The oxide semiconductor layer 16 includes a channel region 16a, a lower region 16b, an upper region 16c, and a void 16x (air gap). The gate electrode 18 includes a first portion 18a and a second portion 18b. The gate insulating layer 20 includes a third portion 20a and a fourth portion 20b.

The lower electrode 12 is an example of the first electrode. The upper electrode 14 is an example of the second electrode. The channel region 16a is an example of the first region. The lower region 16b is an example of the second region. The upper region 16c is an example of the third region.

The lower electrode 12 is provided below the oxide semiconductor layer 16. The lower electrode 12 is electrically connected to the oxide semiconductor layer 16. For example, the lower electrode 12 is in contact with the oxide semiconductor layer 16. The lower electrode 12 functions as a source electrode or a drain electrode of the transistor 100.

The lower electrode 12 is a conductor. For example, the lower electrode 12 includes an oxide conductor. For example, the lower electrode 12 is an oxide conductor layer.

For example, the lower electrode 12 contains indium (In), tin (Sn), and oxygen (O). For example, the lower electrode 12 contains indium tin oxide. For example, the lower electrode 12 is an indium tin oxide layer.

For example, the lower electrode 12 contains tin (Sn) and oxygen (O). For example, the lower electrode 12 contains tin oxide. For example, the lower electrode 12 is a tin oxide layer.

For example, the lower electrode 12 contains metal. For example, the lower electrode 12 is a metal layer.

For example, the lower electrode 12 contains tungsten (W), molybdenum (Mo), copper (Cu), aluminum (Al), titanium (Ti), or tantalum (Ta). For example, the lower electrode 12 is a tungsten layer, a molybdenum layer, a copper layer, an aluminum layer, a titanium layer, or a tantalum layer.

For example, the lower electrode 12 may have a stacked structure of a plurality of conductors. For example, the lower electrode 12 has a stacked structure of an oxide conductor layer and a metal layer. For example, a surface of the lower electrode 12 on a side of the oxide semiconductor layer 16 is an oxide conductor layer.

The upper electrode 14 is provided on the oxide semiconductor layer 16. The upper electrode 14 is electrically connected to the oxide semiconductor layer 16. For example, the upper electrode 14 is in contact with the oxide semiconductor layer 16. The upper electrode 14 functions as a source electrode or a drain electrode of the transistor 100.

The upper electrode 14 is a conductor. For example, the upper electrode 14 includes an oxide conductor. For example, the upper electrode 14 is an oxide conductor layer.

For example, the upper electrode 14 contains indium (In), tin (Sn), and oxygen (O). For example, the upper electrode 14 contains indium tin oxide. For example, the upper electrode 14 is an indium tin oxide layer.

For example, the upper electrode 14 contains tin (Sn) and oxygen (O). For example, the upper electrode 14 contains tin oxide. For example, the upper electrode 14 is a tin oxide layer.

For example, the upper electrode 14 contains metal. For example, the upper electrode 14 is a metal layer.

For example, the upper electrode 14 contains tungsten (W), molybdenum (Mo), copper (Cu), aluminum (Al), titanium (Ti), or tantalum (Ta). For example, the upper electrode 14 is a tungsten layer, a molybdenum layer, a copper layer, an aluminum layer, a titanium layer, or a tantalum layer.

For example, the upper electrode 14 may have a stacked structure of a plurality of conductors. For example, the upper electrode 14 has a stacked structure of an oxide conductor layer and a metal layer. For example, a surface of the upper electrode 14 on a side of the oxide semiconductor layer 16 is an oxide conductor layer.

For example, the lower electrode 12 and the upper electrode 14 are formed of the same material. For example, the lower electrode 12 and the upper electrode 14 are oxide conductors containing indium (In), tin (Sn), and oxygen (O). For example, the lower electrode 12 and the upper electrode 14 contain indium tin oxide. For example, the lower electrode 12 and the upper electrode 14 are indium tin oxide layers.

The oxide semiconductor layer 16 is provided between the lower electrode 12 and the upper electrode 14. For example, the oxide semiconductor layer 16 is in contact with the lower electrode 12. For example, the oxide semiconductor layer 16 is in contact with the upper electrode 14.

A channel serving as a current path is formed in the oxide semiconductor layer 16 when power is turned on to operate the transistor 100.

The oxide semiconductor layer 16 is an oxide semiconductor. For example, the oxide semiconductor layer 16 is amorphous.

For example, the oxide semiconductor layer 16 contains at least one element selected from the group consisting of zinc (Zn), gallium (Ga), silicon (Si), aluminum (Al), and tin (Sn), and indium (In), and oxygen (O). For example, the oxide semiconductor layer 16 contains indium (In), gallium (Ga), zinc (Zn), and oxygen (O). For example, the oxide semiconductor layer 16 contains indium gallium zinc oxide. For example, the oxide semiconductor layer 16 is an indium gallium zinc oxide layer.

For example, the oxide semiconductor layer 16 contains at least one element selected from the group consisting of titanium (Ti), zinc (Zn), and tungsten (W), and oxygen (O). For example, the oxide semiconductor layer 16 contains titanium oxide, zinc oxide, or tungsten oxide. For example, the oxide semiconductor layer 16 is a titanium oxide layer, a zinc oxide layer, or a tungsten oxide layer.

For example, the oxide semiconductor layer 16 has a chemical composition different from a chemical composition of the lower electrode 12 and a chemical composition of the upper electrode 14.

The oxide semiconductor layer 16 contains an oxygen vacancy. The oxygen vacancy inside the oxide semiconductor layer 16 functions as a donor.

For example, a length of the oxide semiconductor layer 16 in the first direction is 50 nm or greater and 200 nm or less. For example, a length of the oxide semiconductor layer 16 in the second direction is 10 nm or greater and 100 nm or less.

The oxide semiconductor layer 16 includes the channel region 16a, the lower region 16b, the upper region 16c, and the void 16x.

The channel region 16a faces the gate electrode 18. The channel region 16a is separated from the lower electrode 12 and the upper electrode 14. In the channel region 16a, a channel through which electrons flow is formed when the transistor 100 is in a turned-on state.

The lower region 16b is provided between the channel region 16a and the lower electrode 12. The lower region 16b is in contact with the channel region 16a. The lower region 16b is in contact with the lower electrode 12. The lower region 16b functions as a source region or a drain region of the transistor 100.

The upper region 16c is provided between the channel region 16a and the upper electrode 14. The upper region 16c is in contact with the channel region 16a. The upper region 16c is in contact with the upper electrode 14. The upper region 16c functions as a source region or a drain region of the transistor 100.

The void 16x is a region that does not contain a solid material. For example, the void 16x contains a gas therein. For example, the void 16x is in contact with the channel region 16a. For example, the void 16x is surrounded by the channel region 16a. The oxide semiconductor layer 16 may not include the void 16x.

The gate electrode 18 faces the oxide semiconductor layer 16. The gate electrode 18 faces the channel region 16a of the oxide semiconductor layer 16. The gate electrode 18 is provided such that a position coordinate in the first direction of the gate electrode 18 has a value of each position coordinate of the lower electrode 12 and the upper electrode 14 in the first direction.

As shown in FIG. 2, the gate electrode 18 surrounds the oxide semiconductor layer 16. The gate electrode 18 is provided around the oxide semiconductor layer 16. The gate electrode 18 surrounds the channel region 16a.

The gate electrode 18 is a conductor. For example, the gate electrode 18 is metal, a metal compound, or a semiconductor. For example, the gate electrode 18 contains tungsten (W).

For example, the length of the gate electrode 18 in the first direction is 10 nm or greater and 100 nm or less.

The gate electrode 18 includes the first portion 18a and a second portion 18b in a first cross section parallel to the first direction. In the second direction, the oxide semiconductor layer 16 is provided between the first portion 18a and the second portion 18b. In the second direction, the channel region 16a is provided between the first portion 18a and the second portion 18b.

The gate insulating layer 20 is provided between the gate electrode 18 and the oxide semiconductor layer 16. The gate insulating layer 20 is provided between the gate electrode 18 and the channel region 16a, between the gate electrode 18 and the lower region 16b, and between the gate electrode 18 and the upper region 16c.

As shown in FIG. 2, the gate insulating layer 20 surrounds the oxide semiconductor layer 16. The gate insulating layer 20 surrounds the channel region 16a. The gate insulating layer 20 is provided between the lower electrode 12 and the upper electrode 14.

The gate insulating layer 20 is provided between the first interlayer insulating layer 22 and the lower region 16b. The gate insulating layer 20 is provided between the second interlayer insulating layer 24 and the upper region 16c.

The gate insulating layer 20 is separated from the lower electrode 12. For example, the gate insulating layer 20 is in contact with the upper electrode 14.

For example, the gate insulating layer 20 is an oxide, a nitride, or an oxynitride. For example, the gate insulating layer 20 contains silicon oxide, aluminum oxide, titanium oxide, tantalum oxide, hafnium oxide, silicon nitride, aluminum nitride, or silicon oxynitride. For example, the gate insulating layer 20 is a silicon oxide layer, an aluminum oxide layer, a titanium oxide layer, a tantalum oxide layer, a hafnium oxide layer, a silicon nitride layer, an aluminum nitride layer, or a silicon oxynitride layer.

For example, the gate insulating layer 20 may have a stacked structure. For example, the gate insulating layer 20 has a stacked structure of a silicon nitride layer and a silicon oxide layer. For example, the gate insulating layer 20 has a stacked structure of a silicon nitride layer in contact with the gate electrode 18 and a silicon oxide layer in contact with the oxide semiconductor layer 16. For example, a thickness of the gate insulating layer 20 is 2 nm or greater and 10 nm or less.

The gate insulating layer 20 includes the third portion 20a and a fourth portion 20b in a first cross section parallel to the first direction. In the second direction, the oxide semiconductor layer 16 is provided between the third portion 20a and the fourth portion 20b. In the second direction, the channel region 16a is provided between the third portion 20a and the fourth portion 20b.

In the first cross section parallel to the first direction, a maximum length of the channel region 16a in the second direction is defined as a first length (L1 in FIG. 1). In the first cross section parallel to the first direction, a minimum length of the lower region 16b in the second direction is defined as a second length (L2 in FIG. 1). In the first cross section parallel to the first direction, a minimum length of the upper region 16c in the second direction is defined as a third length (L3 in FIG. 1).

The first length L1 is equal to a maximum distance between the third portion 20a and the fourth portion 20b of the gate insulating layer 20 while the channel region 16a is interposed therebetween. The second length L2 is equal to a minimum distance between the third portion 20a and the fourth portion 20b of the gate insulating layer 20 while the lower region 16b is interposed therebetween. The third length L3 is equal to a minimum distance between the third portion 20a and the fourth portion 20b of the gate insulating layer 20 while the upper region 16c is interposed therebetween.

The first length L1 is greater than the second length L2 and the third length L3. ½ of a difference between the first length L1 and an average value of the second length L2 and the third length L3 is defined as a second thickness (t2 in FIG. 1). That is, t2=(L1−(L2+L3)/2)/2.

As shown in FIG. 1, the second thickness t2 corresponds to a thickness of a portion in which the channel region 16a is embedded toward the first portion 18a of the gate electrode 18.

For example, the second thickness t2 is equal to or greater than 0.75 times and equal to or less than twice the first thickness (t1 in FIG. 1) of the gate insulating layer 20 in the second direction. For example, the second thickness t2 is equal to or greater than one time and equal to or less than 1.5 times the first thickness t1.

For example, the second thickness t2 is 3 nm or greater and 5 nm or less.

For example, a first distance (d1 in FIG. 1) in the first direction between the gate insulating layer 20 and the lower electrode 12 is equal to or greater than twice and equal to or less than ten times the second thickness t2. For example, the first distance d1 is 10 nm or greater and 30 nm or less.

The first interlayer insulating layer 22 is provided between the lower electrode 12 and the gate electrode 18. For example, in a cross section perpendicular to the first direction, the first interlayer insulating layer 22 surrounds the lower region 16b of the gate insulating layer 20 and the oxide semiconductor layer 16. The first interlayer insulating layer 22 is in contact with the gate insulating layer 20.

The second interlayer insulating layer 24 is provided between the gate electrode 18 and the upper electrode 14. For example, in the cross section perpendicular to the first direction, the second interlayer insulating layer 24 surrounds the upper region 16c of the gate insulating layer 20 and the oxide semiconductor layer 16. The second interlayer insulating layer 24 is in contact with the gate insulating layer 20.

The first interlayer insulating layer 22 and the second interlayer insulating layer 24 are insulators. For example, the first interlayer insulating layer 22 and the second interlayer insulating layer 24 are oxides, nitrides, or oxynitrides. For example, the first interlayer insulating layer 22 and the second interlayer insulating layer 24 contain silicon (Si) and oxygen (O). For example, the first interlayer insulating layer 22 and the second interlayer insulating layer 24 contain silicon oxide. For example, the first interlayer insulating layer 22 and the second interlayer insulating layer 24 are silicon oxide layers. For example, the first interlayer insulating layer 22 and the second interlayer insulating layer 24 contain silicon (Si) and nitrogen (N). For example, the first interlayer insulating layer 22 and the second interlayer insulating layer 24 contain silicon nitride. For example, the first interlayer insulating layer 22 and the second interlayer insulating layer 24 are silicon nitride layers.

The first interlayer insulating layer 22 and the second interlayer insulating layer 24 may be formed of different materials.

Next, an example of a method for manufacturing the semiconductor device of the first embodiment will be described.

In the method for manufacturing a semiconductor device according to the first embodiment, the method includes forming a first insulating film on a first conductive film, forming a second conductive film on the first insulating film, forming a second insulating film on the second conductive film, etching the second insulating film, the second conductive film, and the first insulating film to form an opening in which the second conductive film is exposed on an inner surface of the opening, etching the second conductive film exposed on the inner surface to form a recess portion, forming a third insulating film inside the opening and the recess portion, forming a first film embedding the recess portion inside the opening, etching the first film inside the opening such that the first film embedding the recess portion remains, etching the third insulating film or the first insulating film exposed on a bottom surface of the opening to expose the first conductive film on the bottom surface of the opening, removing the first film embedding the recess portion, and forming an oxide semiconductor film inside the opening.

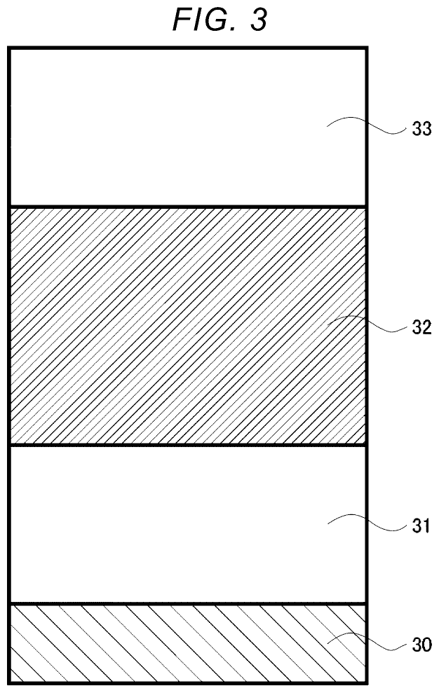

FIGS. 3, 4, 5, 6, 7, 8, 9, 10, 11, 12, and 13 schematically illustrate cross-sectional view of elements to show example process steps of the method for manufacturing the semiconductor device according to the first embodiment. FIGS. 3 to 13 each show cross sections corresponding to FIG. 1. FIGS. 3 to 13 show an example of a method for manufacturing the transistor 100.

Hereinafter, a case where the lower electrode 12 of the transistor 100 is an indium tin oxide layer, the upper electrode 14 is an indium tin oxide layer, the oxide semiconductor layer 16 is an indium gallium zinc oxide layer, the gate electrode 18 is a tungsten layer, the gate insulating layer 20 is a silicon oxide layer, the first interlayer insulating layer 22 and the second interlayer insulating layer 24 are silicon oxide layers will be described as an example.

First, a first silicon oxide film 31, a tungsten film 32, and a second silicon oxide film 33 are formed on a first indium tin oxide film 30 (FIG. 3). For example, the first silicon oxide film 31, the tungsten film 32, and the second silicon oxide film 33 are formed by using a chemical vapor deposition method (CVD method).

The first indium tin oxide film 30 is an example of the first conductive film. The first silicon oxide film 31 is an example of the first insulating film. The tungsten film 32 is an example of the second conductive film. The second silicon oxide film 33 is an example of the second insulating film.

The first indium tin oxide film 30 ultimately serves as the lower electrode 12. A portion of the first silicon oxide film 31 ultimately serves as the third interlayer insulating layer 22. A portion of the tungsten film 32 ultimately serves as the gate electrode 18. A portion of the second silicon oxide film 33 ultimately serves as the second interlayer insulating layer 24.

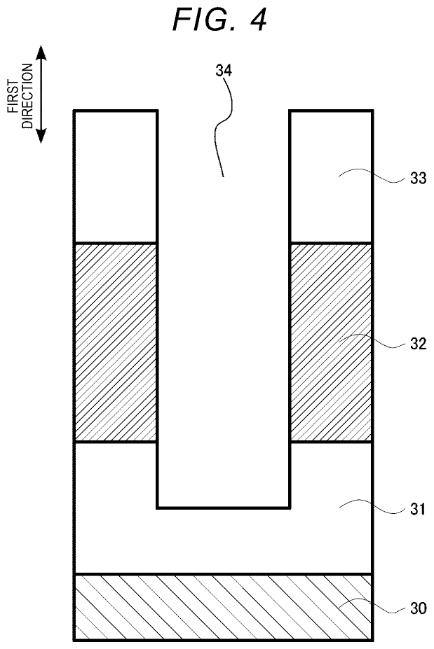

Next, the second silicon oxide film 33, the tungsten film 32, and the first silicon oxide film 31 are etched to form an opening 34 (FIG. 4). The opening 34 penetrates the second silicon oxide film 33 and the tungsten film 32. For example, the opening 34 is formed by using a lithography method and a reactive ion etching method (RIE method). The tungsten film 32 is exposed on an inner surface of the opening 34. The first silicon oxide film 31 is exposed on a bottom surface of the opening 34. The opening 34 extends in the first direction.

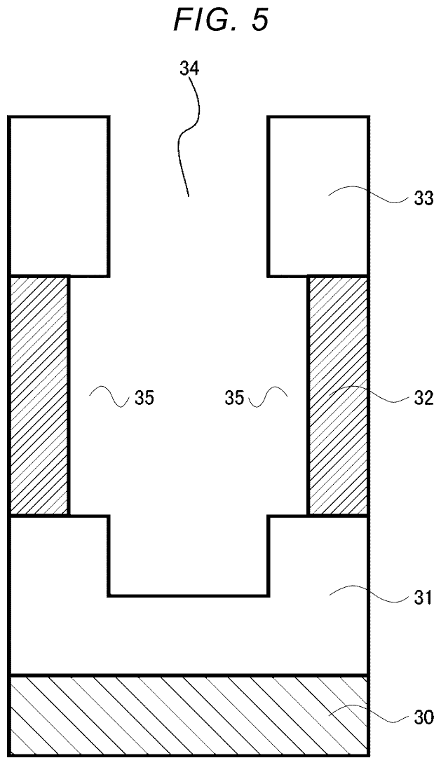

Next, the tungsten film 32 exposed on the inner surface of the opening 34 is etched to form a recess portion 35 (FIG. 5). The recess portion 35 is a portion where the tungsten film 32 retreats in a horizontal direction from the first silicon oxide film 31 and the second silicon oxide film 33. For example, the tungsten film 32 is etched by using a wet etching method.

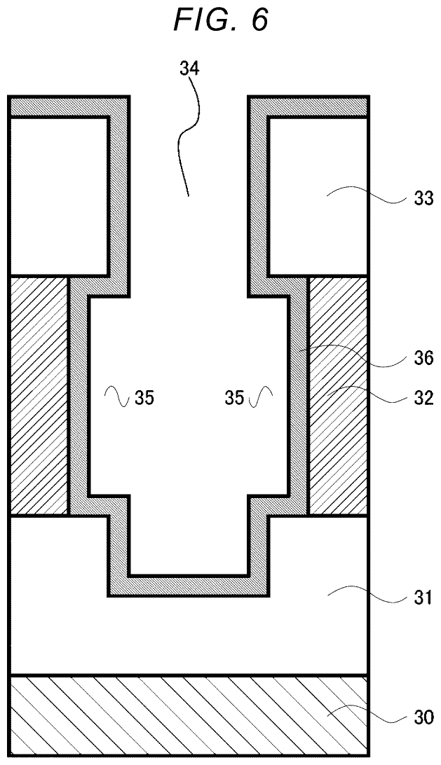

Next, a stacked film 36 of the silicon nitride film and the silicon oxide film is formed inside the opening 34 and the recess portion 35 (FIG. 6). For example, the stacked film 36 is formed by using an ALD method. The stacked film 36 is an example of the third insulating film. The stacked film 36 ultimately serves as the gate insulating layer 20.

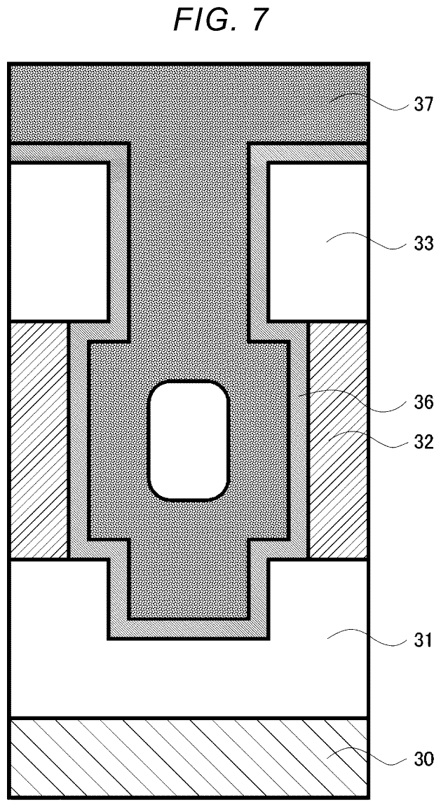

Next, a carbon film 37 in which the recess portion 35 is embedded is formed inside the opening 34 (FIG. 7). For example, the inside of the opening 34 is completely embedded with the carbon film 37. For example, the carbon film 37 is a coating type carbon film formed by using a spin coating method. The carbon film 37 is an example of the first film.

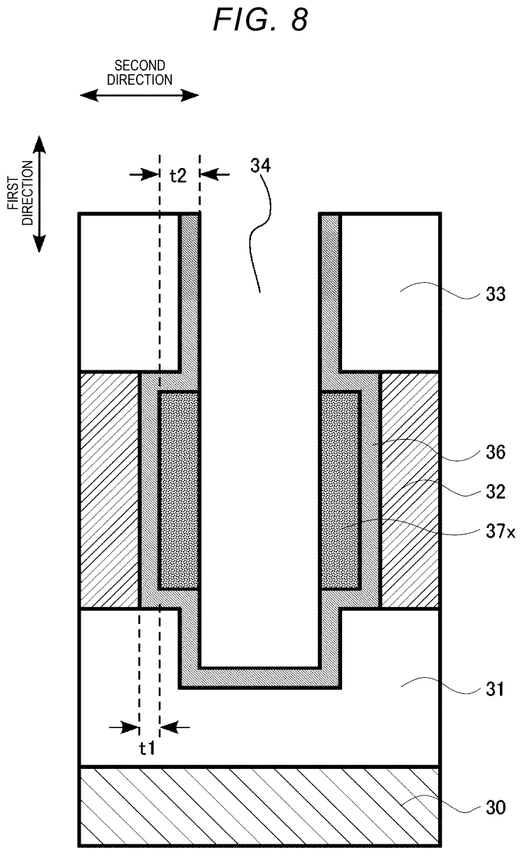

Next, the carbon film 37 inside the opening 34 is removed by etching (FIG. 8). When the carbon film 37 is etched, the carbon film 37 in which the recess portion 35 is embedded remains. A portion 37x of the carbon film 37 remains in the recess portion 35. The stacked film 36 is exposed on the bottom surface of the opening 34. The stacked film 36 functions as an etching stopper film when the carbon film 37 is etched.

For example, the etching of the carbon film 37 is performed by using an RIE method. Since the RIE method is anisotropic etching, the portion 37x of the carbon film 37 can remain in the recess portion 35. For example, a mixed gas of an oxygen gas, a nitrogen gas, and a carbon monoxide gas is used as an etching gas when the carbon film 37 is etched.

For example, the second thickness (t2 in FIG. 8) of the portion 37x of the carbon film 37 remaining in the recess portion 35 after the carbon film 37 is etched in the second direction perpendicular to the first direction is equal to or greater than 0.75 times and equal to or less than twice the first thickness (t1 in FIG. 8) of the stacked film 36 in the second direction.

For example, the first thickness is 2 nm or greater and 8 nm or less. For example, the second thickness is 3 nm or greater and 5 nm or less.

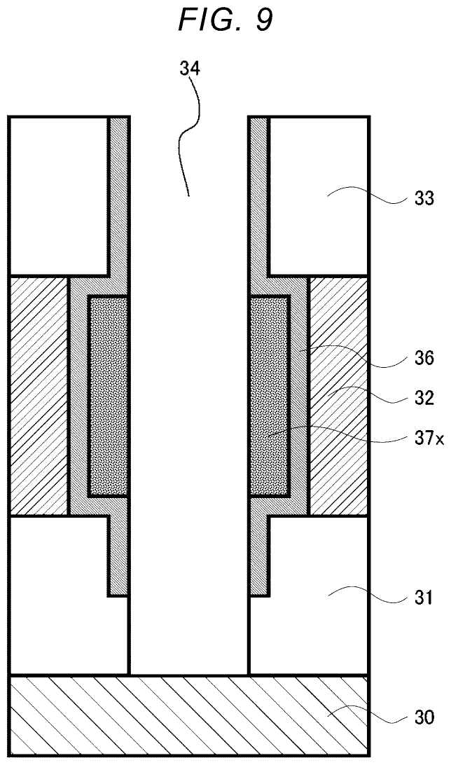

Next, the stacked film 36 on the bottom surface of the opening 34 is etched and removed. Furthermore, the first silicon oxide film 31 exposed on the bottom surface of the opening 34 is etched and removed. The first indium tin oxide film 30 is exposed on the bottom surface of the opening 34 (FIG. 9).

The etching of the stacked film 36 and the etching of the first silicon oxide film 31 are performed by using the RIE method. The portion 37x of the carbon film 37 remaining in the recess portion 35 functions as a protective film of the stacked film 36 when the stacked film 36 is etched and the first silicon oxide film 31 is etched.

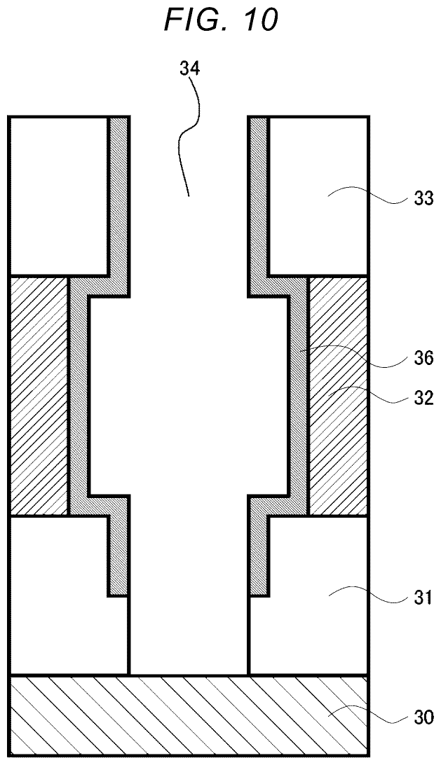

Next, the portion 37x of the carbon film 37 remaining in the recess portion 35 is removed (FIG. 10). For example, the portion 37x of the carbon film 37 is removed by an ashing method using an oxygen plasma.

The ashing method is isotropic etching using the oxygen plasma. In the ashing method, the oxygen plasma or an oxygen radical generated from the oxygen plasma reacts with the portion 37x of the carbon film 37. The portion 37x of the carbon film 37 is removed by causing the oxygen plasma or the oxygen radical to react with the portion 37x of the carbon film 37.

For example, the portion 37x of the carbon film 37 is removed by using the ashing method at a temperature of 20° C. or higher and 100° C. or lower.

For example, the etching of the carbon film 37, the etching of the stacked film 36, the etching of the first silicon oxide film 31, and the removal of the portion 37x of the carbon film 37 are continuously performed inside the same etching chamber. For example, the etching of the carbon film 37, the etching of the stacked film 36, the etching of the first silicon oxide film 31, and the removal of the portion 37x of the carbon film 37 are continuously performed in the same RIE chamber.

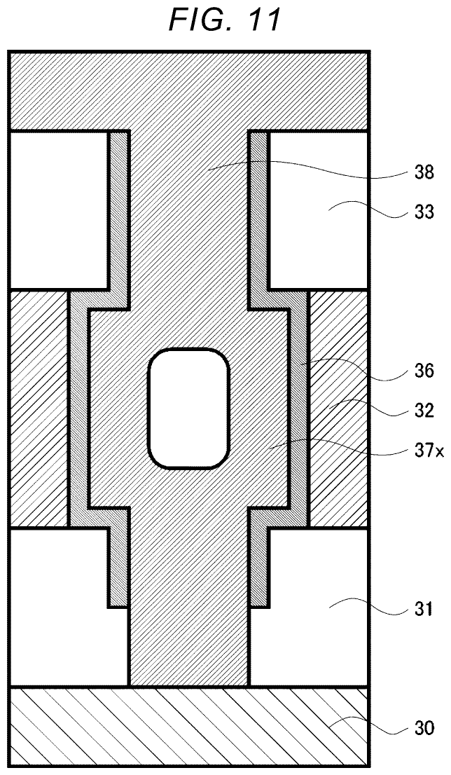

Next, an indium gallium zinc oxide film 38 is formed inside the opening 34 (FIG. 11). For example, the indium gallium zinc oxide film 38 is formed by using an ALD method. The indium gallium zinc oxide film 38 is an example of the oxide semiconductor film. A portion of the indium gallium zinc oxide film 38 ultimately serves as the oxide semiconductor layer 16.

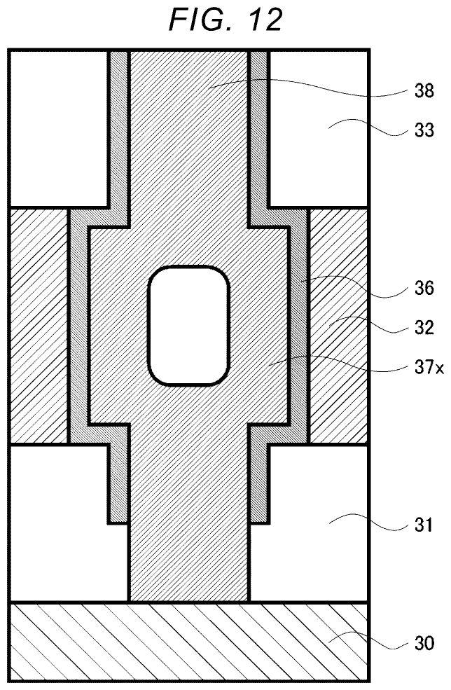

Next, the indium gallium zinc oxide film 38 on a surface of the second silicon oxide film 33 is removed, and the indium gallium zinc oxide film 38 remains only inside the opening 34 (FIG. 12). For example, an upper portion of the indium gallium zinc oxide film 38 is removed by using a chemical mechanical polishing method (CMP method).

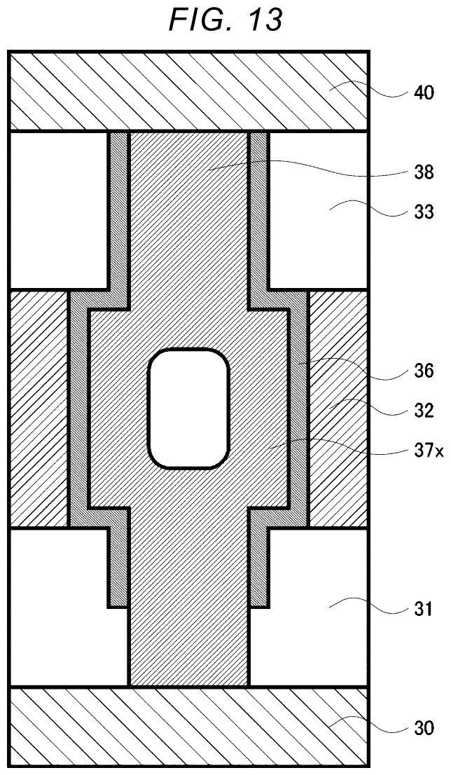

Next, a second indium tin oxide film 40 is formed on the indium gallium zinc oxide film 38 (FIG. 13). For example, the second indium tin oxide film 40 is formed by using a sputtering method. The second indium tin oxide film 40 ultimately serves as the upper electrode 14.

The transistor 100 shown in FIGS. 1 and 2 is manufactured by using the above-described manufacturing method.

Although a case where the first film is the carbon film 37 is described as an example, other films are also applicable as long as the film is formed of a material that can be embedded in the recess portion 35 and has a high etching selection ratio with respect to the third insulating film. For example, an amorphous silicon film can be applicable as the first film.

In addition, although a case where the inside of the opening 34 is completely embedded with the carbon film 37 was described as an example, a method can also be adopted in which only a portion inside the opening 34 is embedded with the carbon film 37.

In addition, although a case where the stacked film 36 remains on the bottom surface of the opening 34 when the carbon film 37 inside the opening 34 is removed by the etching is described as an example, the first silicon oxide film 31 may be exposed on the bottom surface of the opening 34.

Next, operations and advantageous effects of the semiconductor device of the first embodiment will be described.

An oxide semiconductor transistor that forms a channel in an oxide semiconductor layer has excellent characteristics in that a channel leakage current is extremely small when operating power is turned off. Therefore, for example, a study was made to apply an oxide semiconductor transistor to a switching transistor of a memory cell of a DRAM. Since a channel leak current is extremely small when operating power is turned off, charge holding capability of the DRAM is improved by applying the oxide semiconductor transistor to the switching transistor.

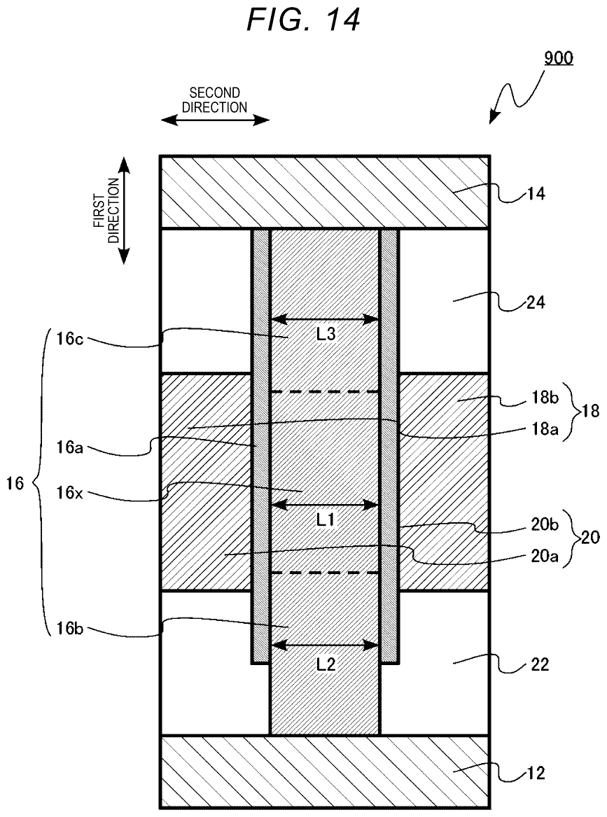

FIG. 14 schematically illustrates a cross-sectional view of a semiconductor device according to a comparative example. FIG. 14 corresponds to FIG. 1 illustrating the semiconductor device according to the first embodiment.

The semiconductor device according to the comparative example is a transistor 900. The transistor 900 is the oxide semiconductor transistor. The transistor 900 is different from the transistor 100 according to the first embodiment in the following point. In the first cross section parallel to the first direction, the first length (L1 in FIG. 14) which is the maximum length of the channel region 16a in the second direction is equal to the second length (L2 in FIG. 14) which is the minimum length of the lower region 16b in the second direction, and the third length (L3 in FIG. 14) which is the minimum length of the upper region 16c in the second direction.

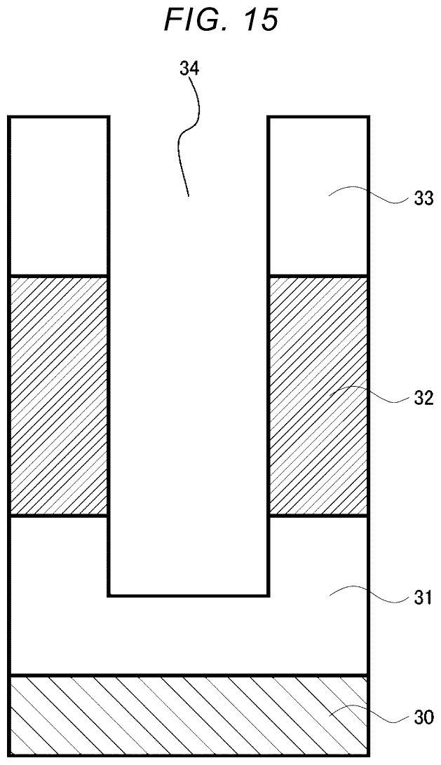

FIGS. 15, 16, 17, and 18 schematically illustrate cross-sectional views of elements to show example process steps of a method for manufacturing the semiconductor device according to the comparative example. FIGS. 15 to 18 each show cross sections corresponding to FIG. 14. FIGS. 15 to 18 show examples of a method for manufacturing the transistor 900.

The method for manufacturing the transistor 900 is the same as the method for manufacturing the semiconductor device according to the first embodiment until the second silicon oxide film 33, the tungsten film 32, and the first silicon oxide film 31 are etched to form the opening 34 (FIG. 15).

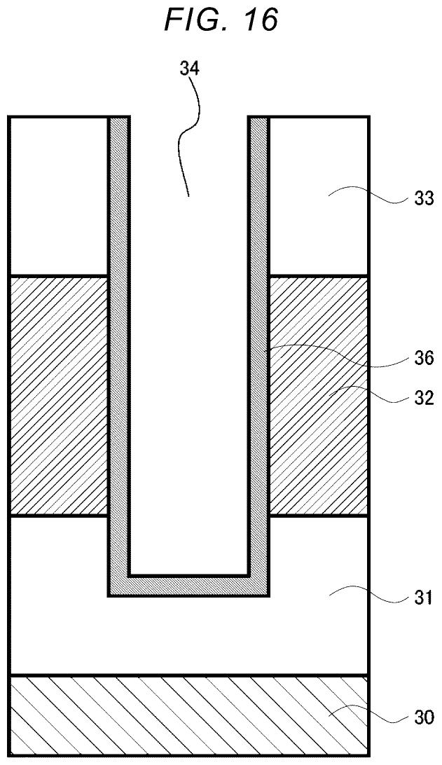

Next, the recess portion 35 as in the first embodiment is not formed, and the stacked film 36 of the silicon nitride film and the silicon oxide film is formed inside the opening 34 (FIG. 16). The stacked film 36 ultimately serves as the gate insulating layer 20.

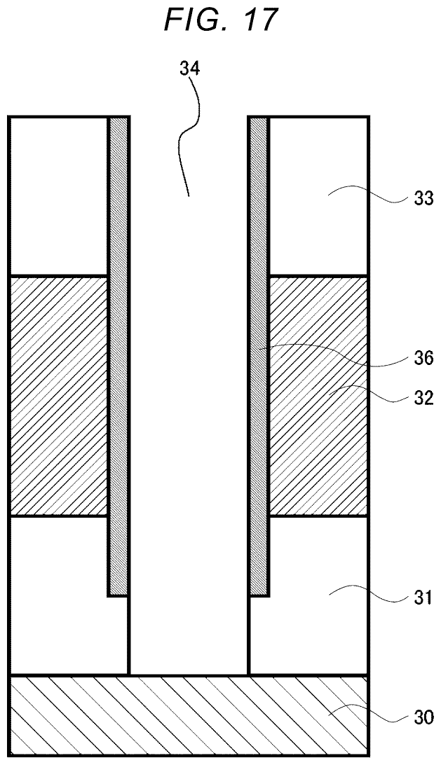

Next, the stacked film 36 on the bottom surface of the opening 34 is etched and removed. Furthermore, the first silicon oxide film 31 exposed on the bottom surface of the opening 34 is etched and removed. The first indium tin oxide film 30 is exposed on the bottom surface of the opening 34 (FIG. 17).

The etching of the stacked film 36 and the etching of the first silicon oxide film 31 are performed by using the RIE method.

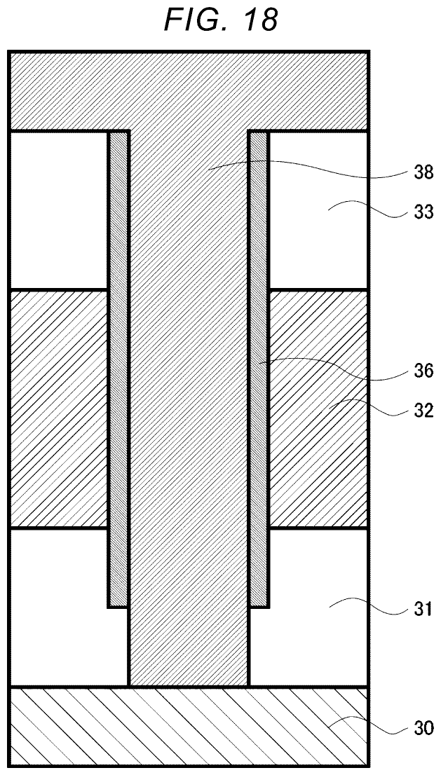

Next, the indium gallium zinc oxide film 38 is formed inside the opening 34 (FIG. 18). A portion of the indium gallium zinc oxide film 38 ultimately serves as the oxide semiconductor layer 16.

Thereafter, as in the first embodiment, the indium gallium zinc oxide film 38 on the surface of the second silicon oxide film 33 is removed. The second indium tin oxide film 40 is formed on the indium gallium zinc oxide film 38.

The transistor 900 shown in FIG. 14 is manufactured by using the above-described manufacturing method.

In the method for manufacturing the transistor 900 according to the comparative example, when the stacked film 36 on the bottom surface of the opening 34 is etched and the first silicon oxide film 31 is etched by using the RIE method, the stacked film 36 facing the tungsten film 32 is exposed on the inner surface of the opening 34 (FIG. 17). Therefore, the stacked film 36 is exposed to the etching, and processing damage due to an ion impact is added. Therefore, for example, reliability of the gate insulating layer 20 of the transistor 900 is lowered.

In the method for manufacturing the semiconductor device according to the first embodiment, when the stacked film 36 on the bottom surface of the opening 34 is etched and the first silicon oxide film 31 is etched by using the RIE method, the stacked film 36 facing the tungsten film 32 is covered with the portion 37x of the carbon film 37 (FIG. 9). The portion 37x of the carbon film 37 functions as a protective film that protects the stacked film 36 during the etching. Therefore, the stacked film 36 is not exposed to the etching, and the processing damage due to the ion impact is not added. Therefore, for example, the reliability of the gate insulating layer 20 of the transistor 100 is improved.

From a viewpoint of reducing the processing damage due to the ion impact and improving the reliability of the gate insulating layer 20, it is preferable that the second thickness (t2 in FIG. 8) of the portion 37x of the carbon film 37 in the second direction is thicker. From the above-described viewpoint, it is preferable that the second thickness t2 is equal to or greater than 0.75 times the first thickness (t1 in FIG. 8) of the stacked film 36 in the second direction, and is more preferable that the second thickness t2 is equal to or greater than one time the first thickness.

From the above-described viewpoint, it is preferable that the second thickness t2 is 3 nm or greater, and is more preferable that the second thickness t2 is 5 nm or greater.

It is preferable that the etching selection ratio between the first film and the third insulating film is higher when the first film inside the opening 34 is etched such that the first film in which the recess portion 35 is embedded remains. From a viewpoint of raising the etching selection ratio between the first film and the third insulating film, it is preferable that the first film is a carbon film. For example, when the third insulating film is the stacked film 36 of the silicon nitride film and the silicon oxide film, the etching selection ratio can be raised by setting the first film as the carbon film.

In addition, when the first film in which the recess portion 35 is embedded is removed, it is preferable that the first film is removed by using the ashing method having less processing damage from a viewpoint of reducing the processing damage added to the third insulating film that ultimately serves as the gate insulating layer 20. Since the first film is set as the carbon film, the first film can be removed by using the ashing method. Furthermore, from a viewpoint of reducing the processing damage added to the third insulating film, it is preferable that the carbon film is removed by using the ashing method at a temperature of 100° C. or lower.

In the transistor 100 of the first embodiment, in the first cross section parallel to the first direction, the first length (L1 in FIG. 1) which is the maximum length of the channel region 16a in the second direction is greater than the second length (L2 in FIG. 1) which is the minimum length of the lower region 16b in the second direction. In addition, the first length (L1 in FIG. 1) of the channel region 16a is greater than the third length (L3 in FIG. 1) which is the minimum length of the upper region 16c in the second direction.

The transistor 100 of the first embodiment having the above-described configuration is manufactured by using the method for manufacturing the semiconductor device according to the first embodiment. The method for manufacturing the semiconductor device according to the first embodiment uses the first film in which the recess portion 35 is embedded, as the protective film, and therefore, the reliability of the gate insulating layer 20 of the transistor 100 of the first embodiment is improved.

From a viewpoint of improving the reliability of the gate insulating layer 20, it is preferable that the second thickness t2 is equal to or greater than 0.75 times the first thickness (t1 in FIG. 1) of the gate insulating layer 20 in the second direction, and is more preferable that the second thickness t2 is equal to or greater than one time. The second thickness t2 is a value of ½ of a difference between the first length L1 and the average value of the second length L2 and the third length L3.

In the transistor 100 of the first embodiment, the gate insulating layer 20 is separated from the lower electrode 12. For example, a leakage current passing the gate insulating layer 20 between the gate electrode 18 and the lower electrode 12 may increase in some cases. In particular, when the gate insulating layer 20 contains the silicon nitride, the leakage current may increase in some cases.

In the transistor 100 of the first embodiment, the gate insulating layer 20 is separated from the lower electrode 12. Therefore, for example, even when the gate insulating layer 20 contains the silicon nitride, the leakage current between the gate electrode 18 and the lower electrode 12 can be reduced.

It is preferable that the first distance (d1 in FIG. 1) in the first direction between the gate insulating layer 20 and the lower electrode 12 is equal to or greater than twice and equal to or less than 10 times the second thickness t2. Since the above-described condition is satisfied, transistor characteristics of the transistor 100 of the first embodiment are improved.

According to the first embodiment, the reliability of the gate insulating layer 20 is improved, and the semiconductor device having excellent transistor characteristics and the method for manufacturing a semiconductor device can be provided.

### Modification Example

A semiconductor device according to a modification example of the first embodiment is different from the semiconductor device according to the first embodiment in that the gate insulating layer is in contact with the first electrode. Hereinafter, some of repeated contents of the first embodiment may be omitted in the description in some cases.

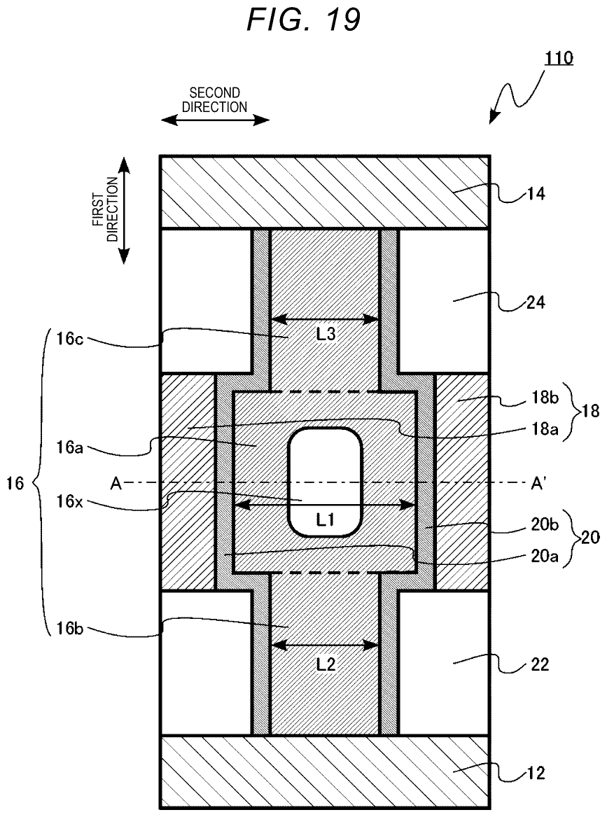

FIG. 19 schematically illustrates a cross-sectional view of a semiconductor device according to a first modification example of the first embodiment. FIG. 19 corresponds to FIG. 1 in the first embodiment.

The semiconductor device according to the first modification example of the first embodiment is a transistor 110. The transistor 110 is an oxide semiconductor transistor.

The gate insulating layer 20 of the transistor 110 is in contact with the lower electrode 12.

For example, in the method for manufacturing the semiconductor device according to the first embodiment, the transistor 110 can be manufactured as follows. When the second silicon oxide film 33, the tungsten film 32, and the first silicon oxide film 31 are etched to form the opening 34, the first indium tin oxide film 30 is exposed on the bottom surface of the opening 34.

According to the first modification example of the first embodiment, as in the first embodiment, the reliability of the gate insulating layer 20 is improved, and a semiconductor device having excellent transistor characteristics and a method for manufacturing a semiconductor device can be provided.

As described above, according to the first embodiment and the modification example, the reliability of the gate insulating layer 20 is improved, and the semiconductor device having the excellent transistor characteristics and the method for manufacturing the semiconductor device can be provided.

### Second Embodiment

A semiconductor memory device according to a second embodiment includes the semiconductor device according to the first embodiment and a capacitor electrically connected to either the first electrode or the second electrode.

The semiconductor memory device according to the second embodiment is a semiconductor memory 200. The semiconductor memory device according to the second embodiment is a DRAM. The semiconductor memory 200 uses the transistor 100 of the first embodiment, as a switching transistor of a memory cell of the DRAM.

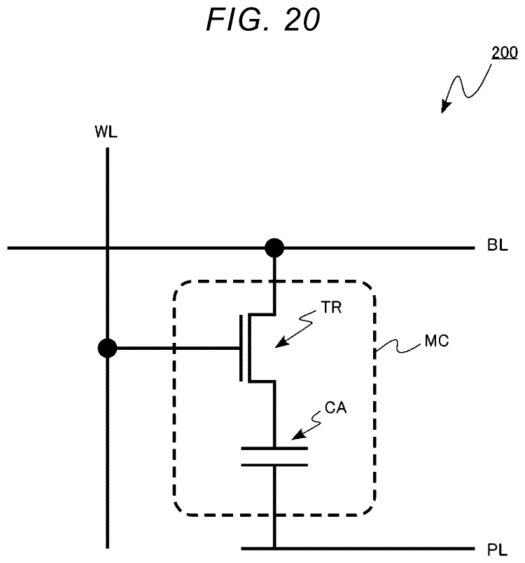

Hereinafter, some of repeated contents of the first embodiment will be omitted in the description. FIG. 20 is an equivalent circuit diagram of the semiconductor memory device according to the second embodiment. Although FIG. 20 shows when one memory cell MC is provided, a plurality of memory cells MC may be provided in an array shape.

The semiconductor memory 200 includes the memory cell MC, a word line WL, a bit line BL, and a plate line PL. The memory cell MC includes a switching transistor TR and a capacitor CA. In FIG. 20, a region surrounded by a broken line is the memory cell MC.

The word line WL is electrically connected to a gate electrode of the switching transistor TR. The bit line BL is electrically connected to one of source and drain electrodes of the switching transistor TR. One electrode of the capacitor CA is electrically connected to the other of the source and drain electrodes of the switching transistor TR. The other electrode of the capacitor CA is connected to the plate line PL.

The memory cell MC stores data by storing electric charges in the capacitor CA. Data is written and read by turning on power to operate the switching transistor TR.

For example, power is turned on to operate the switching transistor TR in a state where a desired voltage is applied to the bit line BL, and data is written to the memory cell MC.

In addition, for example, power is turned on to operate the switching transistor TR, a voltage change of the bit line BL according to the amount of the electric charges stored in the capacitor is detected, and the data of the memory cell MC is read.

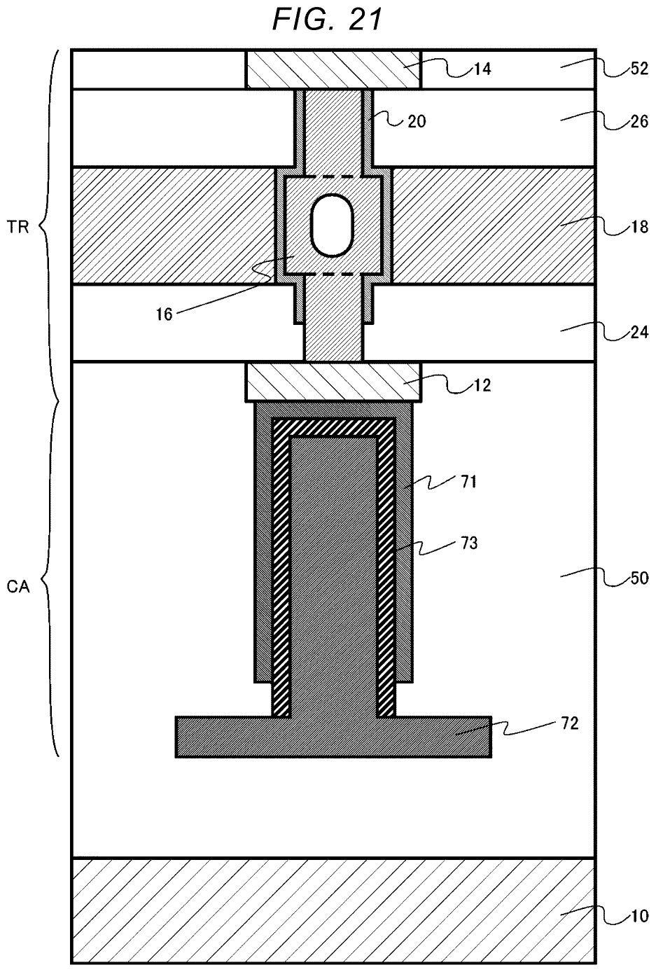

FIG. 21 schematically illustrates a cross-sectional view of the semiconductor memory device according to the second embodiment. FIG. 21 shows a cross section of the memory cell MC of the semiconductor memory 200.

The semiconductor memory 200 includes a silicon substrate 10, the switching transistor TR, the capacitor CA, a lower insulating layer 50, and an upper insulating layer 52.

The switching transistor TR includes the lower electrode 12, the upper electrode 14, the oxide semiconductor layer 16, the gate electrode 18, the gate insulating layer 20, the first interlayer insulating layer 22, and the second interlayer insulating layer 24.

The switching transistor TR has the same structure as the transistor 100 of the first embodiment.

The capacitor CA is provided between the silicon substrate 10 and the switching transistor TR. The capacitor CA is provided between the silicon substrate 10 and the lower electrode 12. The capacitor CA is electrically connected to the lower electrode 12. The capacitor CA can be electrically connected to the upper electrode 14.

The capacitor CA includes a cell electrode 71, a plate electrode 72, and a capacitor insulating film 73. The cell electrode 71 is electrically connected to the lower electrode 12. For example, the cell electrode 71 is in contact with the lower electrode 12.

For example, the cell electrode 71 and the plate electrode 72 are formed of titanium nitride. For example, the capacitor insulating film 73 has a stacked structure of zirconium oxide, aluminum oxide, and zirconium oxide.

For example, the gate electrode 18 is electrically connected to the word line WL (not shown). For example, the upper electrode 14 is electrically connected to the bit line BL (not shown). For example, the plate electrode 72 is connected to the plate line PL (not shown).

The semiconductor memory 200 employs an oxide semiconductor transistor having an extremely small channel leak current when operating power is turned off, for the switching transistor TR. Therefore, the DRAM having excellent charge holding capability is provided.

In addition, the switching transistor TR of the semiconductor memory 200 has high reliability of the gate insulating layer 20. Therefore, the reliability of the semiconductor memory 200 is improved.

Although a so-called GAA Transistor was described as an example in the first embodiment, the transistor of the present disclosure is not limited to the GAA Transistor, and, for example, the transistor of the present disclosure may be a transistor in which only a portion of the oxide semiconductor layer faces the gate electrode.

Although the semiconductor memory to which the transistor of the first embodiment is applied is used as an example in the second embodiment, the semiconductor memory of the embodiment of the present disclosure may be a semiconductor memory to which the transistor according to the modification example of the first embodiment is applied.

According to the semiconductor memory device of the second embodiment, the semiconductor memory device having the excellent transistor characteristics can be provided.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first electrode;
a second electrode;
an oxide semiconductor layer provided between the first electrode and the second electrode in a first direction, and including a first region, a second region provided between the first region and the first electrode in the first direction, and a third region provided between the first region and the second electrode in the first direction;
a gate electrode facing the first region; and
a gate insulating layer provided between the first region and the gate electrode, separated from the first electrode, and in contact with the second electrode, wherein
in a first cross section parallel to the first direction, a first length, which is a maximum length of the first region in a second direction perpendicular to the first direction, is greater than a second length, which is a minimum length of the second region in the second direction, and greater than a third length, which is a minimum length of the third region in the second direction, and
a second thickness, which is ½ of a difference between the first length and an average value of the second length and the third length, is equal to or greater than 0.75 times a first thickness, which is a thickness of the gate insulating layer in the second direction.

2. The semiconductor device according to claim 1, wherein the gate insulating layer contains silicon nitride.

3. The semiconductor device according to claim 1, wherein the second thickness is equal to or greater than the first thickness.

4. The semiconductor device according to claim 1, wherein a first distance between the gate insulating layer and the first electrode in the first direction is equal to or greater than twice the second thickness and equal to or less than ten times the second thickness.

5. The semiconductor device according to claim 1, wherein the gate electrode surrounds the oxide semiconductor layer.

6. The semiconductor device according to claim 1, wherein the gate insulating layer is in contact with a surface of the first region that faces the first electrode in the first direction, a surface of the first region that faces the second electrode in the first direction, and a surface of the first region that faces the gate electrode in the second direction.

7. The semiconductor device according to claim 1, wherein the first region of the oxide semiconductor layer includes a void therein.

8. A semiconductor memory device comprising:
the semiconductor device according to claim 1; and
a capacitor electrically connected to either the first electrode or the second electrode.

9. A method for manufacturing a semiconductor device, the method comprising:
forming a first insulating film on a first conductive film;
forming a second conductive film on the first insulating film;
forming a second insulating film on the second conductive film;
etching the second insulating film, the second conductive film, and the first insulating film to form an opening in which the second conductive film is exposed on an inner surface of the opening;
etching the second conductive film exposed on the inner surface to form a recess portion;
forming a third insulating film inside the opening and the recess portion;
forming a first film embedding the recess portion inside the opening;
etching the first film inside the opening such that the first film embedding the recess portion remains;
etching the third insulating film or the first insulating film exposed on a bottom surface of the opening to expose the first conductive film on the bottom surface of the opening;
removing the first film embedding the recess portion; and
forming an oxide semiconductor film inside the opening.

10. The method for manufacturing a semiconductor device according to claim 9, wherein the etching of the third insulating film or the first insulating film is performed by using a reactive ion etching method.

11. The method for manufacturing a semiconductor device according to claim 9, wherein
when the opening is formed, the first insulating film is exposed on the bottom surface of the opening, and
when the third insulating film or the first insulating film is etched, the first insulating film is etched.

12. The method for manufacturing a semiconductor device according to claim 11, wherein when the third insulating film or the first insulating film is etched, the third insulating film and the first insulating film are etched.

13. The method for manufacturing a semiconductor device according to claim 9, wherein when the first film is formed, an inside of the opening is embedded with the first film.

14. The method for manufacturing a semiconductor device according to claim 9, wherein the first film is a carbon film.

15. The method for manufacturing a semiconductor device according to claim 14, wherein the removing of the first film is performed by using an ashing method.

16. The method for manufacturing a semiconductor device according to claim 9, wherein the etching of the first film, the etching of the third insulating film or the first insulating film, and the removing of the first film are performed inside the same etching chamber.

17. The method for manufacturing a semiconductor device according to claim 9, wherein the third insulating film contains silicon nitride.

18. The method for manufacturing a semiconductor device according to claim 9, wherein the opening extends in a first direction, and a second thickness of the first film remaining in the recess portion in a second direction perpendicular to the first direction after the first film is etched is equal to or greater than 0.75 times a first thickness of the third insulating film in the second direction.

19. The method for manufacturing a semiconductor device according to claim 18, wherein the second thickness is equal to or greater than the first thickness.
